(19) United States
(12) Patent Application Publication
(10) Pub. No.: US 2025/0280645 A1
(43) Pub. Date: Sep. 4, 2025

(54) SEMICONDUCTOR STRUCTURE AND MANUFACTURING METHOD THEREOF

(71) Applicant: ENKRIS SEMICONDUCTOR, INC., Suzhou (CN)

(72) Inventors: Yudong CHENG, Suzhou (CN); Kai CHENG, Suzhou (CN)

(21) Appl. No.: 19/023,214

(22) Filed: Jan. 15, 2025

(30) Foreign Application Priority Data
Feb. 29, 2024 (CN) 202410232066.7

(51) Int. Cl. H10H 29/855; H10H 20/825; H10H 29/01

(52) U.S. Cl. CPC H10H 29/855; H10H 29/011; H10H 29/0363; H10H 20/825

(57) ABSTRACT

Provided are a semiconductor structure and a manufacturing method thereof according to embodiments of the present disclosure. The semiconductor structure includes: a carrier plate; light-emitting units on the carrier plate and lenses on a side of the light-emitting units away from the carrier plate. Each of the light-emitting units includes a first light-emitting structure, a second light-emitting structure and a third light-emitting structure, that are spaced apart on a surface of the carrier plate and respectively configured to emit light with different wavelengths, the second light-emitting structure surrounds the first light-emitting structure, and the third light-emitting structure surrounds the second light-emitting structure. The lenses respectively correspond to the light-emitting units, and the lenses are configured to converge light emitted by the light-emitting units and mix the colors of the light emitted by the light-emitting units.

### CROSS REFERENCE TO RELATED APPLICATIONS

This application claims priority to Chinese Patent Application No. 2024102320667 entitled “SEMICONDUCTOR STRUCTURE AND MANUFACTURING METHOD THEREOF” filed on Feb. 29, 2024, the entire content of which is incorporated herein by reference.

### TECHNICAL FIELD

The present disclosure relates to the technical field of semiconductors and in particular, to a semiconductor structure and a manufacturing method thereof.

### BACKGROUND

With the development of display technology, light-emitting devices such as Light emitting diodes (LED), Organic light emitting diode (OLED), and Liquid crystal displays (LCD) are widely used in electronic products such as computers, televisions, mobile phones and wearable devices. Micro Light emitting diode (Micro LED) is an emerging technology mainly based on inorganic GaN-based LEDs. Compared Micro LED with LCD and OLED, Micro LED has advantages such as small size, high contrast ratio, low power consumption and long service life, etc. However, the current display effect of Micro LED display panels still needs to be improved, and the manufacturing process of Micro LED display panels is relatively complex, thereby resulting in high production cost.

### SUMMARY

In view of this, a semiconductor structure and a manufacturing method thereof are provided in the present disclosure.

In a first aspect, a semiconductor structure is provided according to the present disclosure. The semiconductor structure includes: a carrier plate; light-emitting units on the carrier plate and lenses on a side of the light-emitting units away from the carrier plate. Each of the light-emitting units includes a first light-emitting structure, a second light-emitting structure and a third light-emitting structure that are spaced apart on a surface of the carrier plate and respectively configured to emit light with different wavelengths, the second light-emitting structure surrounds the first light-emitting structure, and the third light-emitting structure surrounds the second light-emitting structure. The lenses respectively correspond to the light-emitting units, and the lenses are configured to converge light emitted by the light-emitting units.

In a second aspect, a manufacturing method for a semiconductor structure is provided according to the present disclosure. The method includes: forming light-emitting units, where each of the light-emitting units comprises a first light-emitting structure, a second light-emitting structure and a third light-emitting structure that are spaced apart and respectively configured to emit light with different wavelengths, the second light-emitting structure surrounds the first light-emitting structure, and the third light-emitting structure surrounds the second light-emitting structure; bonding the light-emitting units to a carrier plate; and forming lenses on a side of the light-emitting units away from the carrier plate, where the lenses respectively correspond to the light-emitting units, and the lenses are configured to converge light emitted by the light-emitting units.

### BRIEF DESCRIPTION OF DRAWINGS

FIG. 1 is a schematic diagram of a top view for a semiconductor structure according to an embodiment of the present disclosure.

FIG. 2 is a schematic diagram of a section along line AB in FIG. 1.

FIG. 3 is a schematic diagram of a section for a semiconductor structure according to an embodiment of the present disclosure.

FIG. 4 is a schematic diagram of a top view for a light-emitting unit according to an embodiment of the present disclosure.

FIG. 5 is a schematic diagram of a top view for a light-emitting unit according to another embodiment of the present disclosure.

FIG. 6 is a schematic diagram of a top view for a light-emitting unit according to a still another embodiment of the present disclosure.

FIG. 7 is a schematic diagram of a localized section for another semiconductor structure according to an embodiment of the present disclosure.

FIG. 8 is a schematic diagram of a localized section for another semiconductor structure according to an embodiment of the present disclosure.

FIG. 9 is a schematic diagram of a localized section for another semiconductor structure according to an embodiment of the present disclosure.

FIGS. 10 to 18 are schematic diagrams of localized sections for intermediate structures of a light-emitting unit formed by a manufacturing method of a semiconductor structure according to an embodiment of the present disclosure.

FIGS. 19 to 21 are schematic diagrams of localized sections for intermediate structures of a light-emitting unit formed by another manufacturing method of a semiconductor structure according to an embodiment of the present disclosure.

FIGS. 22 and 23 are schematic diagrams of localized sections for intermediate structures formed by another manufacturing method of a semiconductor structure according to an embodiment of the present disclosure.

### DETAILED DESCRIPTION

To enable those in the art to better understand the solution of the present disclosure, the technical solutions in embodiments of the present disclosure will be clearly and completely described below in conjunction with the accompanying drawings in embodiments of the present disclosure. Obviously, the described embodiments are part of embodiments of the present disclosure, but not all of the embodiments. It should be understood that the terms first, second, etc. used in the present disclosure are only used to distinguish the same type of information from each other, but are not necessarily used to describe a specific order or sequence.

A semiconductor structure is provided according to the present disclosure, and this semiconductor structure can mitigate the problem of low luminous intensity of Micro LED, as well as high production cost.

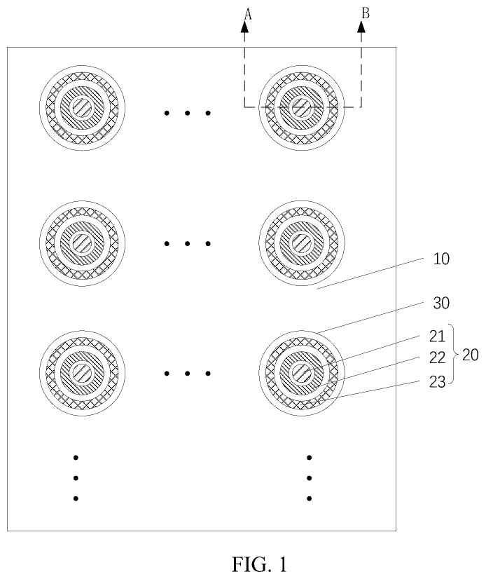

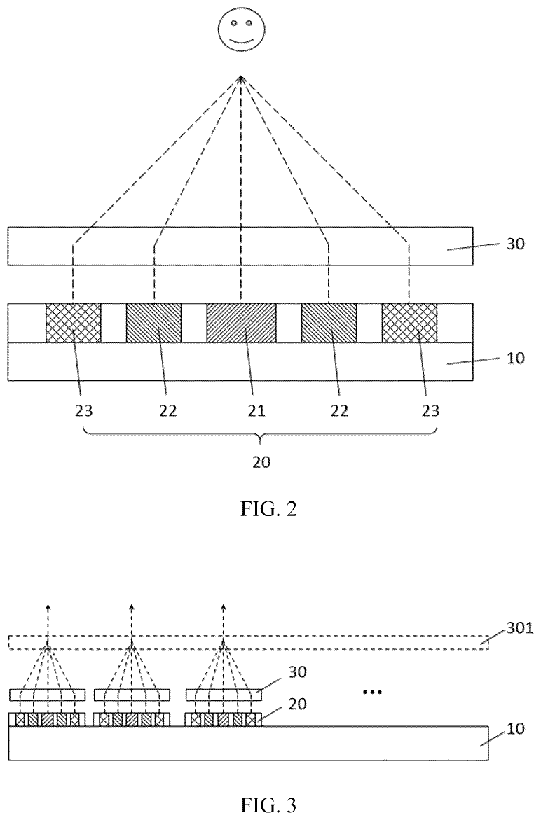

FIG. 1 is a schematic diagram of a top view for a semiconductor structure according to an embodiment of the present disclosure. FIG. 2 is a schematic diagram of a section along line AB in FIG. 1. As shown in FIGS. 1 and 2, a semiconductor structure is provided according to an embodiment of the present disclosure, which includes a carrier plate 10, light-emitting units 20 and lenses 30.

In some embodiments, the carrier plate 10 may include a silicon substrate and a driving circuit layer for driving the light-emitting unit 20.

In some embodiments, the light-emitting units 20 are on the carrier plate 10. As shown in FIG. 1, the light-emitting units 20 are arranged in an array. Each light-emitting unit 20 includes a first light-emitting structure 21, a second light-emitting structure 22 and a third light-emitting structure 23, that are spaced apart on a surface of the carrier plate 10 and respectively configured to emit light with different wavelengths, the second light-emitting structure 22 surrounds the first light-emitting structure 21, and the third light-emitting structure 23 surrounds the second light-emitting structure 22.

In embodiments of the present disclosure, the second light-emitting structure 22 surrounds the first light-emitting structure 21, and the third light-emitting structure 23 surrounds the second light-emitting structure 22, and this arrangement manner can make the distribution of the light with different wavelengths emitted by the first light-emitting structure, the second light-emitting structure and the third light-emitting structure uniform in all directions, and can reduce crosstalk between light with different colors. That is, the distribution of the light on a light-emitting surface of the light-emitting unit 20 is uniform. In addition, the second light-emitting structure 22 and the third light-emitting structure 23 are annular structures, that can help to release stress of the second light-emitting structure 22 and the third light-emitting structure 23 and improve the performance of the light-emitting unit 20.

In some embodiments, each of the first light-emitting structure 21, the second light-emitting structure 22 and the third light-emitting structure 23 may include an N-type semiconductor layer (not shown), an active layer (not shown) and a P-type semiconductor layer (not shown) that are stacked sequentially. Materials of the N-type semiconductor layer may include N-type doped Group III nitride-based materials. The N-type doping element may include at least one of Si, Ge, Sn, Se, or Te. The active layer 22 may include at least one of a single quantum well structure, a multiple quantum well structure, a quantum line structure or a quantum dot structure. Materials of the P-type semiconductor layer may include P-type doped Group III nitride-based materials. The P-type dopant element may be at least one of Mg, Zn, Ca, Sr, or Ba. The group III nitride material may include any one or any combination of GaN, AlGaN, InGaN and AlInGaN.

In some embodiments, the first light-emitting structure 21, the second light-emitting structure 22 and the third light-emitting structure 23 are spaced apart from each other. For example, space between the first light-emitting structure 21, the second light-emitting structure 22 and the third light-emitting structure 23 are filled with a dielectric material, for example, the dielectric material may be silicon dioxide.

In some embodiments, the semiconductor structure may be a Micro Led display panel, and the light-emitting units 20 may be used as pixels that are arranged in an array in the display panel. The first light-emitting structure 21, the second light-emitting structure 22 and the third light-emitting structure 23 may serve as sub-pixels of the display panel. The first light-emitting structure 21, the second light-emitting structure 22 and the third light-emitting structure 23 may respectively emit blue light, green light, and red light.

The lenses 30 are on a side of the light-emitting units 20 away from the carrier plate 10, where the lenses 30 respectively correspond to the light-emitting units 20, and the lenses 30 converge light emitted by the light-emitting units 20. Specifically, a lens 30 is correspondingly disposed on a light-emitting side of a light-emitting unit 20, and the lens 30 can converge the light with different wavelengths emitted by the light-emitting unit 20, thereby achieving the purpose of color mixing and preventing the light emitted by different light-emitting structures from the crosstalk before the light reaching a receiver, thereby avoiding the degradation of the light output effect. In some embodiments, when the semiconductor structure is used for display, the receiver can be the human eye. The light emitted by the semiconductor structure is the light after color mixing to avoid the degradation of the display effect due to the crosstalk of the light. On the other hand, it can be avoided that the human eye recognizes the boundaries of light-emitting structures emitted light with different wavelengths, thereby improving a display experience of a viewer.

In some embodiments, multiple light-emitting structures with different light-emitting wavelengths of the light-emitting unit 20 can be epitaxially manufactured at the same time to avoid the complicated process of massive transfer of RGB colors in the later stage. Therefore, the process difficulty is reduced, and the yield of the semiconductor structure is improved. In an embodiment, an orthographic projection of the light-emitting unit 20 on the carrier plate 10 is within the orthographic projection of the corresponding lens 30 on the carrier plate 10. That is, an area of the orthographic projection of the lens 30 on the carrier plate 10 is greater than or equal to an area of the orthogonal projection of the light-emitting unit 20 on the carrier plate 10. When the area of the orthographic projection of the lens 30 on the carrier plate 10 and the area of the orthographic projection of the light-emitting unit 20 on the carrier plate 10 are equal, the lens 30 can converge the parallel light emitted from the light-emitting unit 20 to achieve color mixing. When the area of the orthographic projection of the lens 30 on the carrier plate 10 is larger than the area of the orthographic projection of the light-emitting unit 20 on the carrier plate 10, the lens 30 further can converge the light emitted obliquely outward from the light-emitting unit 20, which can enhance the intensity of the light emitted from the semiconductor structure in the embodiments of the present disclosure, as well as the luminous efficiency.

In some embodiments, the lens 30 includes a Fresnel lens. The Fresnel lens is a special lens with a zigzag structure that can converge scattered light with a large viewing angle into parallel light and can control the light in the viewing angle. If the light projected to a side of the Fresnel lens is parallel light, the light emitted out from the other side of the Fresnel lens is converged into one point. Specifically, as shown in FIG. 2, a light-emitting unit 20 faces a lens 30. The light-emitting unit 20 emits light of multiple wavelengths in parallel. After the light passing through the lens 30, the light converges and focuses into a point to complete color mixing, thereby improving the display effect.

In some embodiments, a material of the lens 30 may be a transparent material. For example, the material of the lens 30 may include a material with high light transmittance such as organic polymer, glass or etc. where the organic polymer may include polyolefins.

In some embodiments, the material of the lens 30 includes SiO₂, GaN or AlN. The lens 30 is manufactured on the light-emitting unit 20 through a semiconductor process. The process is simple and the light-emitting unit 20 and the lens 30 can be integrated at one time.

In some embodiments, as shown in FIG. 2, the light-emitting unit 20 and the lens 30 are spaced apart from each other by a certain distance.

In some embodiments, FIG. 3 is a schematic diagram of a section for a semiconductor structure according to an embodiment of the present disclosure. As shown in FIG. 3, light-emitting units 20 are disposed on the carrier plate 10, and the light from each light-emitting unit 20 passes through a lens 30 to converge at an imaging position 301 and is subsequently received by the receiver (such as the human eye). Specifically, the imaging position 301 may be a physical structure, or may refer to the convergence position of the light.

In an embodiment, a center of gravity of the orthographic projection of the light-emitting unit 20 on the carrier plate 10 coincides with a center of gravity of the orthographic projection of the lens 30 on the carrier plate 10, which can improve the color mixing effect of the lens 30. In some embodiments, the center of gravity of the orthographic projection of the first light-emitting structure 21 on the carrier plate 10, the center of gravity of the orthographic projection of the second light-emitting structure 22 on the carrier plate 10, and the center of gravity of the orthographic projection of the third light-emitting structure 23 on the carrier plate 10 coincide with each other, which is convenient for the lens 30 to mix colors. In some embodiments, the center of gravity of the orthographic projection of the first light-emitting structure 21 on the carrier plate 10, the center of gravity of the orthographic projection of the second light-emitting structure 22 on the carrier plate 10, and the center of gravity of the orthographic projection of the third light-emitting structure 23 on the carrier plate 10 further coincide with the center of gravity of the orthographic projection of the lens 30 on the carrier plate 10, which further improve the color mixing effect of the lens 30.

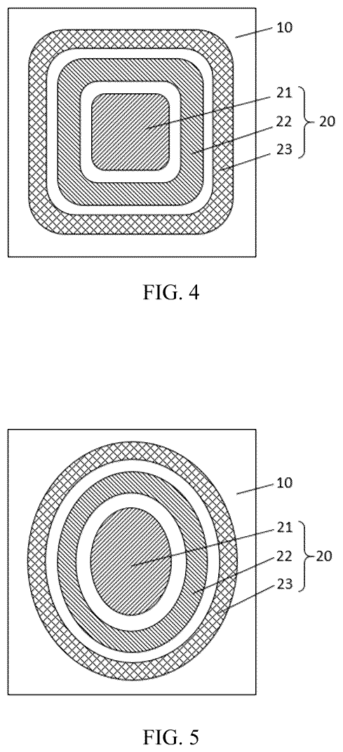

In an embodiment, the orthographic projections of the second light-emitting structure 22 and the third light-emitting structure 23 on the carrier plate 10 are respectively annulus, and the contour shape of the annulus is the same as the contour shape of the first light-emitting structure 21. In an embodiment, as shown in FIG. 1, the orthographic projection of the first light-emitting structure 21 on the carrier plate 10 is a circle, and the orthographic projections of the second light-emitting structure 22 and the third light-emitting structure 23 on the carrier plate 10 are circular annuluses respectively, that is, the shape of the light-emitting structure is the circular or the circular annulus, which helps to release stress and avoid cracking during the process of manufacturing or using. In another embodiment, FIG. 4 is a schematic diagram of a top view for a light-emitting unit according to an embodiment of the present disclosure. As shown in FIG. 4, the orthographic projection of the first light-emitting structure 21 on the carrier plate 10 is a rectangle, and the orthographic projection of the light-emitting structure 22 and the third light-emitting structure 23 on the carrier plate 10 are respectively rectangular annuluses. In another embodiment, FIG. 5 is a schematic diagram of a top view for a light-emitting unit according to an embodiment of the present disclosure. As shown in FIG. 5, the orthographic projection of the first light-emitting structure 21 on the carrier plate 10 is ellipsoidal, and the orthographic projection of the light-emitting structure 22 and the third light-emitting structure 23 on the carrier plate 10 are respectively ellipsoidal annuluses. Specifically, the light emitted by the light-emitting unit 20 is uniformly emitted out from the center of the light-emitting unit 20 along a radiation direction of the contour shape. Therefore, the display device manufactured by the semiconductor structure according to the embodiments of the present disclosure can have an excellent display effect.

In some embodiments, the orthographic projection of the first light-emitting structure 21 on the carrier plate 10 is circular, polygonal, ellipsoidal, or other special-shaped.

As shown in FIG. 1, in an embodiment, a shape of the orthographic projection of the lens 30 on the carrier plate 10 is the same as a shape of the orthographic projection of the light-emitting unit 20 on the carrier plate 10. For example, the light-emitting unit 20 is circular, and the lens 30 is also circular; the light-emitting unit 20 is rectangular, and the lens 30 is also rectangular. The shape of the lens 30 and the shape of the light-emitting unit 20 are the same may result in that the edge(s) of the lens 30 and the edge(s) of the light-emitting unit are parallel, and the parallel light is converged through the lens 30, so the light emitted by the first light-emitting structure 21, the second light-emitting structure 22 and the third light-emitting structure can be better converged. In some embodiments, the area of the orthographic projection of the lens 30 on the carrier plate 10 is greater than or equal to the area of the orthographic projection of the light-emitting unit 20 on the carrier plate 10.

In an embodiment, FIG. 6 is a schematic diagram of a top view for another light-emitting unit according to an embodiment of the present disclosure. As shown in FIG. 6, the second light-emitting structure 22 includes at least two second sub-light-emitting structures which are spaced apart; and/or the third light-emitting structure 23 includes at least two third sub-light-emitting structures which are spaced apart. In some embodiments, the number of the second sub-light-emitting structures may be 2, 3, 4, etc.; or the number of the third sub-light-emitting structures may be 2, 3, 4, etc. As shown in FIG. 6, the second light-emitting substructure 22 includes four second sub-light-emitting structures, and the third light-emitting structure 23 includes eight third sub-light-emitting structures. In some embodiments, the second sub-light-emitting structures can be controlled separately, and the third sub-light-emitting structures can be controlled separately, that may result in that the luminous intensity of the light-emitting structure can be adjusted more flexibly.

In an embodiment, the semiconductor structure includes a first electrode layer 40 and a second electrode layer 50.

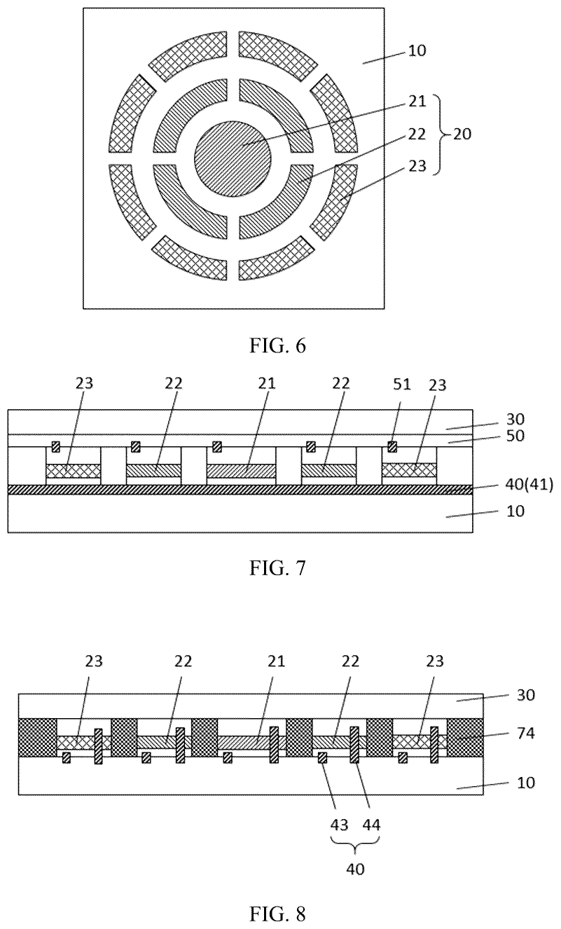

FIG. 7 is a schematic diagram of a localized section for another semiconductor structure according to an embodiment of the present disclosure. As shown in FIG. 7, in some embodiments, the first electrode layer 40 is between the light-emitting unit 20 and the carrier plate 10 and includes first electrodes 41 that are electrically connected to the first light-emitting structure 21, the second light-emitting structure 22 and the third light-emitting structure 23 respectively. The second electrode layer 50 is on the side of the light-emitting unit 20 away from the carrier plate 10 and includes three second electrodes 51 that are electrically connected to the first light-emitting structure 21, the second light-emitting structure 22 and the third light-emitting structure 23 respectively. The second electrodes 51 are electrically isolated from each other. That is, the first electrode 41 is an electrode shared by the first light-emitting structure 21, the second light-emitting structure 22 and the third light-emitting structure 23, so that it is possible to form the first electrode 41 connected to the first light-emitting structure 21, the second light-emitting structure 22, and the third light-emitting structure 23 in a single process, and thus efficiency can be improved. At this time, the carrier plate 10 is not the growth substrate of the light-emitting unit 20.

In some embodiments, the first electrode 41 shared by the first light-emitting structure 21, the second light-emitting structure 22 and the third light-emitting structure 23 may be disposed on the side of the light-emitting unit 20 away from the carrier plate 10. Three second electrodes 51 respectively connected to the first light-emitting structure 21, the second light-emitting structure 22 and the third light-emitting structure 23 are disposed at a side of the light-emitting unit 20 facing the carrier plate 10.

In some embodiments, the materials of the first electrode 41 and the second electrode 51 may be metal materials respectively, for example, the materials of the first electrode 41 and the second electrode 51 may be copper, silver, iron, and alloys thereof respectively.

FIG. 8 is a schematic diagram of a localized section for another semiconductor structure according to an embodiment of the present disclosure. In some embodiments, as shown in FIG. 8, the first electrode layer 40 is between the light-emitting unit 20 and the carrier plate 10 and includes third electrodes 43 and fourth electrodes 44 which are respectively electrically connected to the first light-emitting structure 21, the second light-emitting structure 22 and the third light-emitting structure 23. The first light-emitting structure 21, the second light-emitting structure 22 and the third light-emitting structure 23 all include two semiconductor layers with different conductivity types, the third electrode 43 and the fourth electrode 44 are electrically connected to the two semiconductor layers respectively (e.g. the third electrode 43 is electrically connected to the semiconductor layer with a conductivity type and the fourth electrode 44 is electrically connected to the semiconductor layer with another conductivity type), so that the light emitted by the first light-emitting structure 21, the second light-emitting structure 22 and the third light-emitting structure 23 can be controlled separately.

In some embodiments, the electrical signals of the first electrode layer 40 and the second electrode layer 50 are controlled to achieve full color or white light display. Specifically, taking the semiconductor structure shown in FIG. 7 as an example, a first common signal is provided for the first electrode layer 40 and different second signals are provided for the second electrodes 51 of the first light-emitting structures 21, the second light-emitting structures 22 and the third light-emitting structures 23 in the light-emitting units 20. After the light is mixed by the lens 30, the light-emitting units 20 emit light with different wavelengths ranges and/or different intensity, thereby achieving full color display ultimately. Specifically, taking the semiconductor structure shown in FIG. 7 as an example, a first common signal is provided for the first electrode layer 40 and the same second signals are provided for the second electrodes 51 of the first light-emitting structures 21, the second light-emitting structures 22 and the third light-emitting structures 23 in the light-emitting units 20. After the light is mixed by the lens 30, the light-emitting units 20 emit white light, thereby achieving white display ultimately.

In an embodiment, a light-emitting structure among the first light-emitting structure 21, the second light-emitting structure 22 and the third light-emitting structure 23 emitted light with the largest wavelength has a largest projection area on the carrier plate 10. For example, when the luminous colors of the first light-emitting structure 21, the second light-emitting structure 22 and the third light-emitting structure 23 are blue, green, and red respectively, the projected areas of the first light-emitting structure 21, the second light-emitting structure 22 and the third light-emitting structure 23 on the carrier plate 10 increase sequentially. Since the luminous efficiency of light with different wavelengths is different, the shorter the wavelength, the better the luminous efficiency. An increased area of the light-emitting structure emitted light with a larger emission wavelength may increase the intensity of the light emitted by this light-emitting structure. In addition, the human eye has different sensitivity to light with different wavelengths. Based on above reasons, by designing the area ratios of different light-emitting structures, the intensity of light emitted by the light-emitting structures in the light-emitting unit 20 can be effectively balanced and the problem of a color shift of the display can be mitigated.

In some embodiments, the semiconductor structure provided by this disclosure is used to make a vehicle light array.

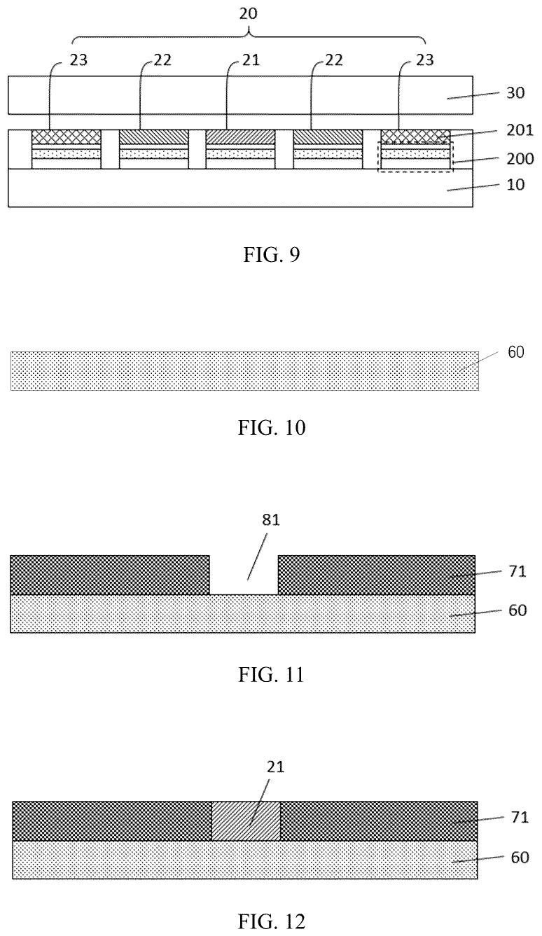

FIG. 9 is a schematic diagram of a localized section for another semiconductor structure according to an embodiment of the present disclosure. In an embodiment, as shown in FIG. 9, each of the light-emitting structures of the light-emitting unit 20 includes a light-emitting layer 200 and a light conversion layer 201 on the light-emitting layer 200, and the light conversion layer 201 is between the light-emitting layer 200 and the lens 30. The light conversion layers 201 of the first light-emitting structure 21, the second light-emitting structure 22 and the third light-emitting structure 23 are different, so that the first light-emitting structure 21, the second light-emitting structure 22 and the third light-emitting structure 23 emitted light with different wavelengths. Specifically, the light-emitting layers 200 of each light-emitting unit 20 emit light with the same wavelength, and then emit out light with different wavelengths after passing through the different light conversion layers 201 of the three light-emitting structures 21/22/23.

In some embodiments, the material of the light conversion layer 201 may be quantum dot or phosphor. Specifically, the light-emitting layer 200 emits white light, yellow light or blue light, the light conversion layer 201 in the first light-emitting structure 21 is provided with blue light quantum dots, and finally emits out blue light; the light conversion layer 201 in the second light-emitting structure 22 is provided with green light quantum dots, and finally emits out green light; and the light conversion layer 201 in the third light-emitting structure 23 is provided with red light quantum dots, and finally emits out red light.

In an embodiment, a manufacturing method for a semiconductor structure is provided according to the present disclosure, which includes the following steps.

Step S1, light-emitting units 20 is formed. Each light-emitting unit 20 includes a first light-emitting structure 21, a second light-emitting structure 22 and a third light-emitting structure 23 that are spaced apart and respectively configured to emit light with different wavelengths. For each light-emitting unit, the second light-emitting structure 22 surrounds the first light-emitting structure 21, and the third light-emitting structure 23 surrounds the second light-emitting structure 22.

Step S2, the light-emitting units 20 and the carrier plate 10 are bonded.

Step S3, lenses 30 are formed on a side of the light-emitting units 20 away from the carrier plate 10. The lenses 30 respectively correspond to the light-emitting units 20. The lenses 30 are configured to converge the light emitted by the light-emitting units 20.

FIGS. 10 to 18 are schematic diagrams of localized sections for intermediate structures of a light-emitting unit formed by a manufacturing method of a semiconductor structure according to an embodiment of the present disclosure. As shown in FIGS. 10 to 18, forming the light-emitting unit 20 includes the following steps.

Step 1101, a growth substrate 60 is provided.

As shown in FIG. 10, the growth substrate 60 may include sapphire, silicon carbide, single crystal silicon, polycrystalline silicon, diamond, gallium nitride, or composite substrate, etc.

Step 1102: a first dielectric layer 71 covering the growth substrate 60 is formed. The first dielectric layer 71 includes at least one first groove 81 exposing the growth substrate 60.

As shown in FIG. 11, the first groove 81 may be formed by etching the first dielectric layer 71 using a mask to expose the growth substrate 60. The shape of an orthographic projection of the first groove 81 on the growth substrate 60 may be circular, polygonal, or ellipsoidal, etc. For example, the shape of the orthographic projection of the first groove 81 on the growth substrate 60 is circular.

Step 1103, the first light-emitting structure 21 is epitaxially manufactured in the first groove 81.

As shown in FIG. 12, the first light-emitting structure 21 may include an N-type semiconductor layer (not shown), an active layer (not shown), and a P-type semiconductor layer (not shown) that are stacked in sequence. In some embodiments, the first light-emitting structure 21 may further include a transparent electrode (not shown). For example, the material of the transparent electrode may be ITO (Indium tin oxide). For example, the first light-emitting structure 21 is used for emitting blue light.

Step 1104: a second dielectric layer 72 covering the first light-emitting structure 21 and the first dielectric layer 71 is formed.

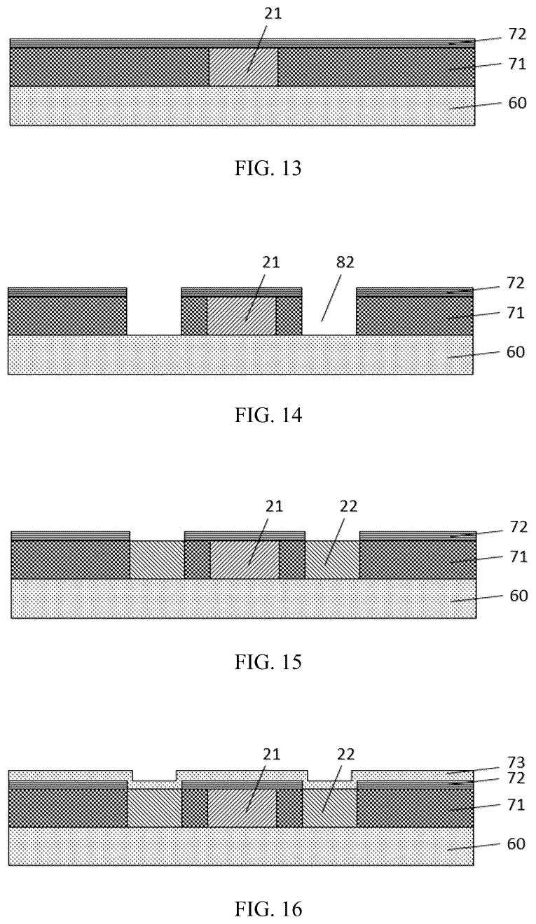

As shown in FIG. 13, the second dielectric layer 72 covers the first light-emitting structure 21 to protect the first light-emitting structure 21 and prevent layers of the second light-emitting structure 22 from being formed on the first light-emitting structure 21 in the subsequent process.

Step 1105, the second dielectric layer 72 is etched to form at least one second groove 82 surrounding the first light-emitting structure 21 and exposing the growth substrate 60.

As shown in FIG. 14, the second groove 82 may be formed by etching the second dielectric layer 72 and the first dielectric layer 71 using a mask to expose the growth substrate 60. For example, the shape of the orthographic projection of the second groove 82 on the growth substrate 60 may be a circular annulus.

Step 1106, the second light-emitting structure 22 is epitaxially manufactured in the second groove 82.

As shown in FIG. 15, the layers of the second light-emitting structure 22 are similar with the layers of the first light-emitting structure 21, and the difference between the layers of the second light-emitting structure 22 and the layers of the first light-emitting structure 21 is that the material of the active layer of the second light-emitting structure 22 is different from the material of the active layer of the first light-emitting structure 21. In some embodiments, the second light-emitting structure 22 is used for emitting green light.

Step 1107: a third dielectric layer 73 covering the second light-emitting structure 22 and the second dielectric layer 72 is formed.

As shown in FIG. 16, the third dielectric layer 73 covers the second light-emitting structure 22 and the second dielectric layer 72. The third dielectric layer 73 is used to prevent the layers of the third light-emitting structure 23 from being formed on the second light-emitting structure 22 in the subsequent process.

Step 1108: the third dielectric layer 73 is etched to form at least one third groove 83 surrounding the second light-emitting structure 22 and exposing the growth substrate 60.

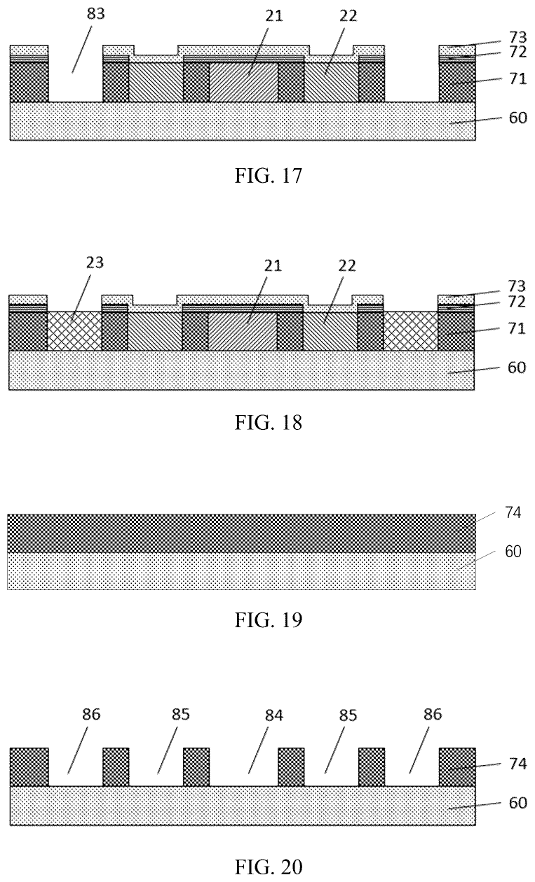

As shown in FIG. 17, the third groove 83 may be formed by etching the third dielectric layer 73, the second dielectric layer 72 and the first dielectric layer 71 using a mask to expose the growth substrate 60. For example, the shape of the orthographic projection of the third groove 83 on the growth substrate 60 may be a circular annulus.

Step 1109, the third light-emitting structure 23 is epitaxially manufactured in the third groove 83.

As shown in FIG. 18, the layers of the third light-emitting structure 23 are similar with the layers of the first light-emitting structure 21, and the difference between the layers of the third light-emitting structure 23 and the layers of the first light-emitting structure 21 is that the material of the active layer of the third light-emitting structure 23 is different from the material of the active layer of the first light-emitting structure 21. In some embodiments, the third light-emitting structure 23 is used for emitting red light.

In some embodiments, after the third light-emitting structure 23 is formed, a planarization process for the first dielectric layer 71, the second dielectric layer 72, and the third dielectric layer 73 is performed to expose the first light-emitting structure 21 and the second light-emitting structure 22.

In some embodiments, after the planarization process, a first electrode layer is formed on the surfaces of the first dielectric layer 71, the first light-emitting structure 21, the second light-emitting structure 22 and the third light-emitting structure 23. The first electrode layer may include a first electrode shared by the first light-emitting structure 21, the second light-emitting structure 22 and the third light-emitting structure 23.

In this embodiment, the first light-emitting structure 21, the second light-emitting structure 22 and the third light-emitting structure 23 that emit light with different colors are formed on one growth substrate 60 using an epitaxial process. By repeating steps 1101-1109, the light emitting units 20 can be obtained. The light-emitting units may be entirely bonded to the carrier plate. This method can simplify the manufacturing process of Micro LED, so the production cost of Micro LED is significantly reduced.

FIGS. 19 to 21 are schematic diagrams of localized sections for intermediate structures of a light-emitting unit formed by another manufacturing method of a semiconductor structure according to an embodiment of the present disclosure. As shown in FIGS. 19 to 21, forming the light-emitting unit 20 includes the following steps.

Step 1201, a growth substrate 60 is provided. In some embodiments, refer to FIG. 10 and step S1101, which will not be repeated here.

Step S1202, as shown in FIG. 19, a fourth dielectric layer 7 covering the growth substrate 60 is formed.

Step S1203, the fourth dielectric layer 74 is etched to form at least one fourth groove 84, at least one fifth groove 85, and at least one sixth groove 86 that expose the growth substrate 60 respectively. The fifth groove 85 surrounds the fourth groove 84, and the sixth groove 86 surrounds the fifth groove 85. The projected areas of the fourth groove 84, the fifth groove 85 and the sixth groove 86 on the growth substrate 60 are different.

As shown in FIG. 20, the fourth dielectric layer may be etched using a mask. In some embodiments, the orthographic projection of the fourth groove 84 on the growth substrate 60 is a circle, and the orthographic projections of the fifth groove 85 and the sixth groove 86 on the growth substrate 60 may be circular annulus.

Step S1204: the first light-emitting structure 21, the second light-emitting structure 22 and the third light-emitting structure 23 emitting light with different wavelengths are respectively manufactured in the fourth groove 84, the fifth groove 85 and the sixth groove 86 in one epitaxial process.

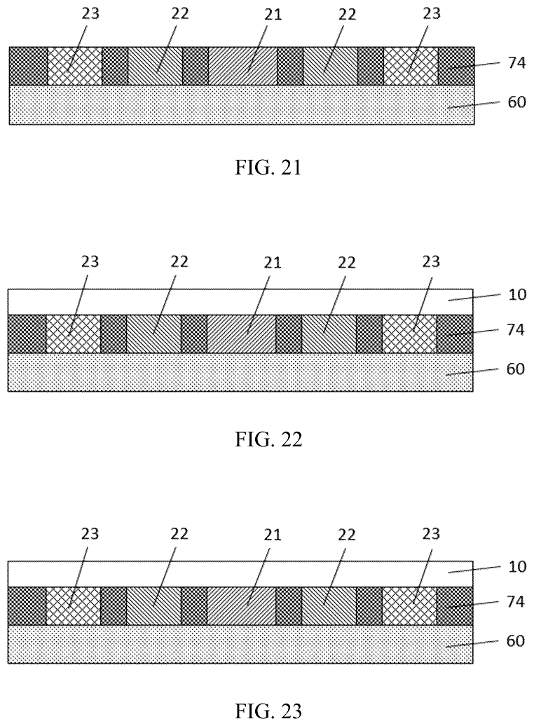

As shown in FIG. 21, the first light-emitting structure 21, the second light-emitting structure 22 and the third light-emitting structure 23 emitting light with different wavelengths may be manufactured in one epitaxial process using the same process parameters. Since the sizes of the fourth groove 84, the fifth groove 85 and the sixth groove 86 are different, the materials of the active layers formed in different grooves are different under the same conditions, the first light-emitting structure 21, the second light-emitting structure 22 and the third light-emitting structure 23 formed in one epitaxial process respectively emit blue light, green light, and red light.

As shown in FIG. 22, in step S2, bonding the light-emitting unit 20 to the carrier plate 10 may include bonding a side of the light-emitting unit 20 away from the growth substrate 60 to the carrier plate 10.

As shown in FIG. 23, after the light-emitting unit 20 and the carrier plate 10 are bonded, the original growth substrate 60 is peeled off.

In some embodiments, after peeling off the original growth substrate 60, a second electrode layer is formed on the side of the first light-emitting structure 21, the second light-emitting structure 22 and the third light-emitting structure 23 away from the carrier plate 10, and the second electrode layer includes three second electrodes that are electrically connected to the first light-emitting structure 21, the second light-emitting structure 22 and the third light-emitting structure 23 respectively.

As shown in FIG. 2, in step S3, a lens 30 is formed on the side of the light-emitting unit 20 away from the carrier plate 10. There is a distance between the light-emitting unit 20 and the lens 30, and the space between the light-emitting unit 20 and the lens 30 may be used to dispose electrodes and other structures. In some embodiments, when the material of the lens 30 is SiO₂, GaN or AlN, the lens may be manufactured through deposition process or epitaxial process on the surface of the light-emitting unit 20, this process is simple, and the light-emitting unit 20 and the lens 30 can be integrated together in this process. When the material of the lens 30 is organic polymer or glass, the light-emitting unit 20 and the lens 30 can be integrated together through bonding process.

A manufacturing method for a semiconductor structure is provided according to the embodiments of the present disclosure. The first light-emitting structure, the second light-emitting structure and the third light-emitting structure emitted light with different colors are formed on one growth substrate and can be entirely bonded to the carrier plate at the same time.

Compared with the traditional mass transfer process in which the light-emitting structures emitted light with different colors are formed on different growth substrates and then the light-emitting structures emitted light with different colors are transferred to a carrier plate, the manufacturing method for the semiconductor structure according to the embodiments of the present disclosure simplify the manufacturing process of Micro LED, and the production cost of Micro LED is significantly reduced. In the semiconductor structure manufactured by this manufacturing method, the light-emitting unit includes a first light-emitting structure, a second light-emitting structure and a third light-emitting structure. The second light-emitting structure surrounds the first light-emitting structure, and the third light-emitting structure surrounds the second light-emitting structure. The lenses respectively correspond to the light-emitting units, and the lenses are configured to converge light emitted by the light-emitting units and mix the colors of the light emitted by the light-emitting units to avoid crosstalk between the light emitted by different light-emitting structures before the light reaching a receiver, thereby avoiding a reduction of the light-emitting effect.

A semiconductor structure and a manufacturing method thereof are provided according to the embodiments of the present disclosure. The semiconductor structure includes: a carrier plate; light-emitting units on the carrier plate and lenses on a side of the light-emitting units away from the carrier plate. Each of the light-emitting units includes a first light-emitting structure, a second light-emitting structure and a third light-emitting structure, that are spaced apart on a surface of the carrier plate and respectively configured to emit light with different wavelengths, the second light-emitting structure surrounds the first light-emitting structure, and the third light-emitting structure surrounds the second light-emitting structure. The lenses respectively correspond to the light-emitting units, and the lenses converge light emitted by the light-emitting units and mix the colors of the light emitted by the light-emitting units to avoid crosstalk between the light emitted by different light-emitting structures before reaching a receiver, thereby avoiding a reduction of the light-emitting effect.

The foregoing are only some embodiments of the present disclosure and are not intended to limit the present disclosure, and any modifications, equivalent substitutions, improvements, etc., made within the spirit and principles of the present disclosure shall be included within the scope of protection of the present disclosure.

What is claimed is:

1. A semiconductor structure, comprising:
a carrier plate;
light-emitting units on the carrier plate, wherein each of the light-emitting units comprises a first light-emitting structure, a second light-emitting structure and a third light-emitting structure that are spaced apart on a surface of the carrier plate and respectively configured to emit light with different wavelengths, the second light-emitting structure surrounds the first light-emitting structure, and the third light-emitting structure surrounds the second light-emitting structure; and
lenses on a side of the light-emitting units away from the carrier plate, wherein the lenses respectively correspond to the light-emitting units, and the lenses are configured to converge light emitted by the light-emitting units.

2. The semiconductor structure according to claim 1, wherein an orthographic projection of the light-emitting unit on the carrier plate is within an orthographic projection of the corresponding lens on the carrier plate.

3. The semiconductor structure according to claim 2, wherein the lenses comprise Fresnel lens.

4. The semiconductor structure according to claim 3, wherein a material of the lenses comprises one of SiO₂, GaN, AlN, glass or organic polymer material.

5. The semiconductor structure according to claim 2, wherein a center of gravity of the orthographic projection of the light-emitting unit on the carrier plate coincides with a center of gravity of the orthographic projection of the corresponding lens on the carrier plate.

6. The semiconductor structure according to claim 1, wherein orthographic projections of the second light-emitting structure and the third light-emitting structure on the carrier plate are respectively annuluses, and contour shapes of the annuluses are same as a contour shape of the first light-emitting structure.

7. The semiconductor structure according to claim 6, wherein a shape of an orthographic projection of the lens on the carrier plate is same as a shape of an orthographic projection of the light-emitting unit on the carrier plate.

8. The semiconductor structure according to claim 6, wherein the second light-emitting structure further comprises at least two second sub-light-emitting that are spaced apart.

9. The semiconductor structure according to claim 6, wherein the third light-emitting structure further comprises at least two third sub-light-emitting that are spaced apart.

10. The semiconductor structure according to claim 1, wherein the semiconductor structure further comprises:
a first electrode layer between the light-emitting unit and the carrier plate, comprising a first electrode electrically connected to the first light-emitting structure, the second light-emitting structure and the third light-emitting structure respectively;
a second electrode layer on the side of the light-emitting unit away from the carrier plate, comprising three second electrodes electrically connected to the first light-emitting structure, the second light-emitting structure and the third light-emitting structure respectively, wherein the three second electrodes are electrically isolated from each other.

11. The semiconductor structure according to claim 1, wherein a light-emitting structure among the first light-emitting structure, the second light-emitting structure and the third light-emitting structure emitted light with the largest wavelength has the largest projection area on the carrier plate.

12. The semiconductor structure according to claim 1, wherein each of the light-emitting structures comprises a light-emitting layer and a light conversion layer on the light-emitting layer, and the light conversion layer is between the light-emitting layer and the lens; and the light conversion layers of the first light-emitting structure, the second light-emitting structure and the third light-emitting structure are different to make the first light-emitting structure, the second light-emitting structure and the third light-emitting structure emit light with different wavelengths.

13. A manufacturing method of a semiconductor structure, comprising:
forming light-emitting units, wherein each of the light-emitting units comprises a first light-emitting structure, a second light-emitting structure and a third light-emitting structure that are spaced apart and respectively configured to emit light with different wavelengths, the second light-emitting structure surrounds the first light-emitting structure, and the third light-emitting structure surrounds the second light-emitting structure;
bonding the light-emitting units to a carrier plate; and
forming lenses on a side of the light-emitting units away from the carrier plate, wherein the lenses respectively correspond to the light-emitting units, and the lenses converge light emitted by the light-emitting units.

14. The method according to claim 13, wherein forming the light-emitting unit comprises:
providing a growth substrate;
forming a first dielectric layer covering the growth substrate, wherein the first dielectric layer comprises at least one first groove exposing the growth substrate;
epitaxially manufacturing a first light-emitting structure in the at least one first groove;
forming a second dielectric layer covering the first light-emitting structure and the first dielectric layer;
etching the second dielectric layer to form at least one second groove surrounding the first light-emitting structure and exposing the growth substrate;
epitaxially manufacturing a second light-emitting structure in the at least one second groove;
forming a third dielectric layer covering the second light-emitting structure and the second dielectric layer;
etching the third dielectric layer to form at least one third groove surrounding the second light-emitting structure and exposing the growth substrate; and
epitaxially manufacturing a third light-emitting structure in the at least one third groove.

15. The method according to claim 13, wherein forming the light-emitting unit comprises:
providing a growth substrate;
forming a fourth dielectric layer covering the growth substrate;
etching the fourth dielectric layer to form at least one fourth groove, at least one fifth groove, and at least one sixth groove that expose the growth substrate, wherein the at least one fifth groove surround the at least one fourth groove, the at least one sixth groove surround the at least one fifth groove, and projected areas of the at least one fourth groove, the at least one fifth groove and the at least one sixth groove on the growth substrate are different; and
epitaxially manufacturing the first light-emitting structure, the second light-emitting structure and the third light-emitting structure that are configured to emit light with different wavelengths in one epitaxial process in the at least one fourth groove, the at least one fifth groove and the at least one sixth groove respectively.

16. The semiconductor structure according to claim 1, wherein the first light-emitting structure the second light-emitting structure and the third light-emitting structure respectively comprise an N-type semiconductor layer, an active layer, and a P-type semiconductor layer that are stacked in sequence.

17. The semiconductor structure according to claim 16, wherein the N-type semiconductor layer is made of N-type doped Group III nitride-based materials, the P-type semiconductor layer is made of P-type doped Group III nitride-based materials, and group III nitride materials comprises any one or any combination of GaN, AlGaN, InGaN and AlInGaN.

18. The semiconductor structure according to claim 1, wherein the first light-emitting structure, the second light-emitting structure and the third light-emitting structure are spaced apart from each other, space between the first light-emitting structure, the second light-emitting structure and the third light-emitting structure are filled with a dielectric material, and the dielectric material is made of silicon dioxide.

19. The semiconductor structure according to claim 11, wherein the first light-emitting structure, the second light-emitting structure and the third light-emitting structure respectively emit blue light, green light, and red light.

20. The semiconductor structure according to claim 12, wherein the light conversion layer is made of quantum dot or phosphor.
